(19) United States
(12) Patent Application Publication
(10) Pub. No.: US 2022/0077026 A1
(43) Pub. Date: Mar. 10, 2022

(54) Diode and semiconductor structure thereof

(71) Applicant: REALTEK SEMICONDUCTOR CORPORATION, Hsinchu (TW)

(72) Inventors: TAY-HER TSAUR, Hsinchu (TW); KUN-YU TAI, Hsinchu (TW); CHENG-CHENG YEN, Hsinchu (TW)

(21) Appl. No.: 17/460,364

(22) Filed: Aug. 30, 2021

(30) Foreign Application Priority Data
Sep. 4, 2020 (TW) 109130422

(51) Int. Cl. H01L 23/485; H01L 23/528

(52) U.S. Cl. CPC H01L 23/485; H01L 29/417; H01L 23/528

(57) ABSTRACT

A diode, which is implemented in a semiconductor structure, includes a substrate, and first, second, third and fourth conductors. The substrate contains first and second doped regions. The first and second doped regions are used respectively as a first electrode and a second electrode of the diode. The first and third conductors are in a first conductor layer of the semiconductor structure and are connected to the first and second doped regions, respectively. The second and fourth conductors are in a second conductor layer of the semiconductor structure and are connected to the first and third conductors, respectively. In a side view of the semiconductor structure, an overlapping area between the first conductor and the third conductor is larger than an overlapping between of the second conductor and the fourth conductor.

### BACKGROUND OF THE INVENTION

### 1. Field of the Invention

The present invention generally relates to diodes, and, more particularly, to diodes with low Electro Magnetic Interference (EMI) and their semiconductor structures.

### 2. Description of Related Art

FIG. 1 is a functional block diagram of a conventional chip. The chip 100 includes an internal circuit 110, an internal circuit 120, a diode 130, a diode 140, and an input/output (I/O) pad 150. The internal circuit 110 and the internal circuit 120 are responsible for the functions of the chip 100, and the internal circuit 120 receives or outputs signals through the I/O pad 150. The diode 130 is connected in series between the voltage source VDD and the I/O pad 150, and the diode 140 is connected in series between the I/O pad 150 and ground. The diode 130 and the diode 140 can prevent damages to the internal circuit 120 due to electrostatic discharge (ESD).

As integrated circuits become faster and more powerful, the EMI problem on the chip 100 becomes more serious. Generally, it is more effective and costs less to tackle the EMI problem as closer to the source of the signal as possible. Therefore, designing a diode with low EMI has become an important issue in this technical field.

### SUMMARY OF THE INVENTION

In view of the issues of the prior art, an object of the present invention is to provide diodes and their semiconductor structures, so as to make an improvement to the prior art.

A diode is provided. The diode, which is implemented in a semiconductor structure, includes a substrate, a first conductor structure, and a second conductor structure. The substrate includes a first doped region and a second doped region. The first doped region is used as a first electrode of the diode. The second doped region is used as a second electrode of the diode. A dopant in the first doped region is different from a dopant in the second doped region. The first conductor structure, which is arranged above the first doped region and connected to the first doped region, includes a plurality of first conductors. The first conductors are arranged in a plurality of conductor layers of the semiconductor structure, and the first conductors are connected to each other by a plurality of vias. The second conductor structure, which is arranged above the second doped region and connected to the second doped region, includes a plurality of second conductors. The second conductors are arranged in the conductor layers of the semiconductor structure, and the second conductors are connected to each other by a plurality of vias. A cross-sectional side view of the first conductor structure presents a stepped shape.

A diode is also provided. The diode, which implemented in a semiconductor structure, includes a substrate, a first conductor, a second conductor, a third conductor, and a fourth conductor. The substrate includes a first doped region and a second doped region. The first doped region is used as a first electrode of the diode. The second doped region is used as a second electrode of the diode. A dopant in the first doped region is different from a dopant in the second doped region. The first conductor is arranged in a first conductor layer of the semiconductor structure and connected to the first doped region. The second conductor is arranged in a second conductor layer of the semiconductor structure and connected to the first conductor. The third conductor is arranged in the first conductor layer of the semiconductor structure and connected to the second doped region. The fourth conductor is arranged in the second conductor layer of the semiconductor structure and connected to the third conductor. In a cross-sectional side view of the semiconductor structure, an overlapping area between the first conductor and the third conductor is larger than an overlapping area between the second conductor and the fourth conductor.

The diodes of the present invention and their semiconductor structures have a smaller current loop area in comparison with the conventional technology. Therefore, the diodes of the present invention and their semiconductor structures cause less EMI.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 illustrates a functional block diagram of a conventional chip.

FIG. 2 illustrates a diode's layout on a substrate according to an embodiment of the present invention.

FIG. 3 illustrates a semiconductor structure according to an embodiment of the present invention.

FIG. 4A illustrates a first cross-sectional side view of a diode according to an embodiment of the present invention.

FIG. 4B illustrates a second cross-sectional side view of a diode according to an embodiment of the present invention.

FIGS. 5A-5E illustrate multiple cross-sectional top views of a diode according to an embodiment of the present invention.

FIG. 6 illustrates a first cross-sectional side view of a diode according to another embodiment of the present invention.

FIGS. 7A-7E illustrate multiple cross-sectional top views of a diode according to another embodiment of the present invention.

FIG. 8 illustrates a diode's layout on a substrate according to another embodiment of the present invention.

FIGS. 9A-9E illustrate multiple cross-sectional top views of a diode according to another embodiment of the present invention.

FIG. 10 illustrates the shapes of conductors according to another embodiment of the present invention.

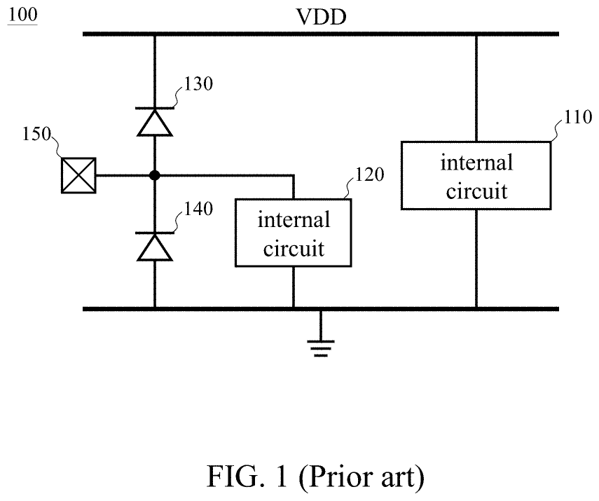

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

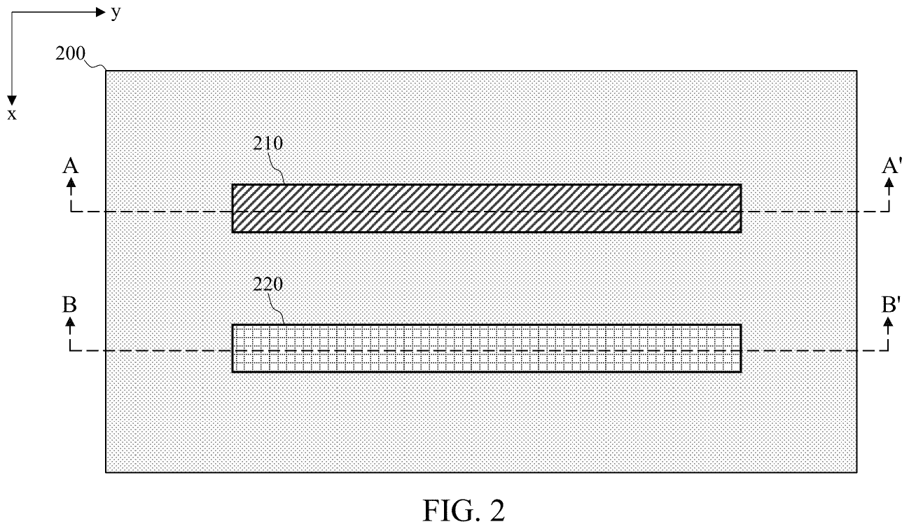

FIG. 2 shows a diode's layout on a substrate according to an embodiment of the present invention. A doped region 210 and a doped region 220 are formed on the substrate 200. The doped region 210 is an N-type doped region (i.e., the cathode of the diode), and the doped region 220 is a P-type doped region (i.e., the anode of the diode). In other words, the dopant in the doped region 210 is different from the dopant in the doped region 220. In some embodiments, the doped region 210 and the doped region 220 are substantially parallel to each other.

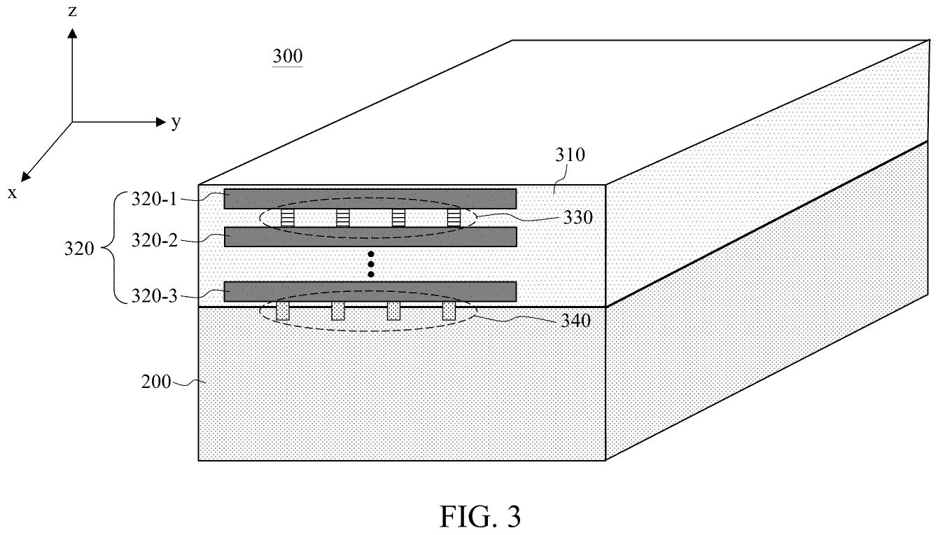

FIG. 3 shows a semiconductor structure according to an embodiment of the invention. The semiconductor structure 300 includes a substrate 200 and an oxide layer 310 arranged above (in the z direction) the substrate 200. Inside the oxide layer 310, there are a plurality of conductor layers 320 (including at least the conductor layer 320-1, the conductor layer 320-2, and the conductor layer 320-3). Adjacent conductor layers are connected through multiple vias 330, and the conductor layer 320-3 and the substrate 200 are connected through multiple contacts 340. In some embodiments, from bottom to top (i.e., from close to the substrate 200 to far from the substrate 200), the conductor layers 320 in order include the metal layer 1 (M1), the metal layer 2 (M2), the metal layer 3 (M3), . . . , the Ultra-thick metal (UTM) layer, and the Re-distribution layer (RDL). FIG. 2 is a top view (the x-y plane) of the substrate 200.

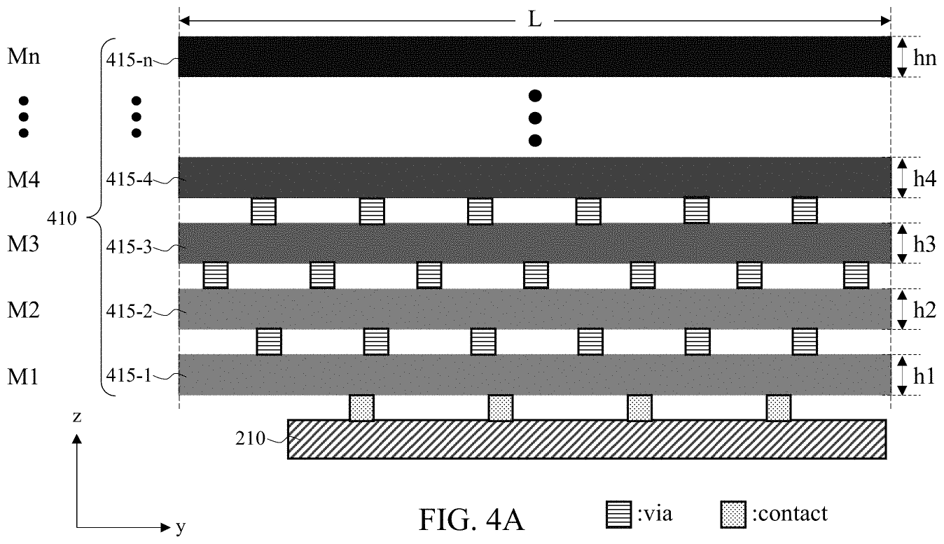

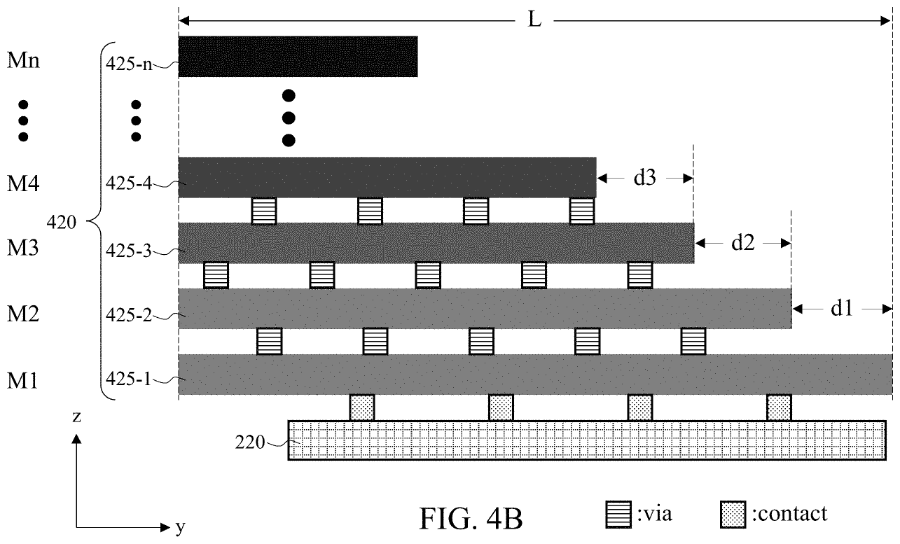

FIG. 4A is a first cross-sectional side view (the y-z plane) of a diode according to an embodiment of the present invention (corresponding to the cross section A-A′ in FIG. 2), and FIG. 4B is a second cross-sectional side view of the diode according to an embodiment of the present invention (corresponding to the cross section B-B′ in FIG. 2).

As shown in FIG. 4A, there is a conductor structure 410 above the doped region 210, and the doped region 210 and the conductor structure 410 are connected through a plurality of contacts. In other words, the conductor structure 410 is the cathode of the diode. The conductor structure 410 includes a plurality of conductors 415 (i.e., the conductor 415-1, conductor 415-2, conductor 415-3, conductor 415-4, . . . , conductor 415-n, where n is an integer greater than one). Adjacent conductors 415 are connected through a plurality of vias. Therefore, the multiple conductors 415 of the conductor structure 410 are substantially equipotential. From bottom to top, the conductor 415-1 is arranged in the metal layer M1 (having a thickness of h1), the conductor 415-2 is arranged in the metal layer M2 (having a thickness of h2), the conductor 415-3 is arranged in the metal layer M3 (having a thickness of h3), the conductor 415-4 is arranged in the metal layer M4 (having a thickness of h4), . . . , the conductor 415-n is arranged in the metal layer Mn (having a thickness of hn). In some embodiments, the conductors 415-1 to 415-n are substantially equal in length (L).

As shown in FIG. 4B, there is a conductor structure 420 above the doped region 220, and the doped region 220 and the conductor structure 420 are connected through a plurality of contacts. In other words, the conductor structure 420 is the anode of the diode. The conductor structure 420 includes a plurality of conductors 425 (i.e., the conductor 425-1, conductor 425-2, conductor 425-3, conductor 425-4, . . . , conductor 425-n). Adjacent conductors 425 are connected through a plurality of vias. Therefore, the multiple conductors 425 of the conductor structure 420 are substantially equipotential. From bottom to top, the conductor 425-1 is arranged in the metal layer M1, the conductor 425-2 is arranged in the metal layer M2, the conductor 425-3 is arranged in the metal layer M3, the conductor 425-4 is arranged in the metal layer M4, . . . , the conductor 425-n is arranged in the metal layer Mn. The conductor structure 420 presents a stepped shape: the conductor 425-1 being longer than the conductor 425-2 by a length of d1, the conductor 425-2 being longer than the conductor 425-3 by a length of d2, the conductor 425-3 being longer than the conductor 425-4 by a length of d3, . . . , and the conductor 425-n being the shortest conductor in the conductor structure 420. In other words, the conductors in the conductor structure 420 are different in length. As shown in FIG. 4B, the conductors 425 in the conductor structure 420 are arranged in a way that their ends on the left side of the side view are substantially aligned. However, the same ends of the conductors being substantially aligned is not a limitation of the present invention. In some embodiments, the lengths of the conductor 425-1, the conductor 425-2, the conductor 425-3, the conductor 425-4, . . . , and the conductor 425-n are in an arithmetic sequence (i.e., d1=d2=d3).

As shown in FIGS. 2, 3, and 4A-4B, the diode of the present invention is a three-dimensional structure which is implemented in the semiconductor structure 300 and includes the doped regions 210 and 220 on the substrate 200, the conductor structure 410, and the conductor structure 420.

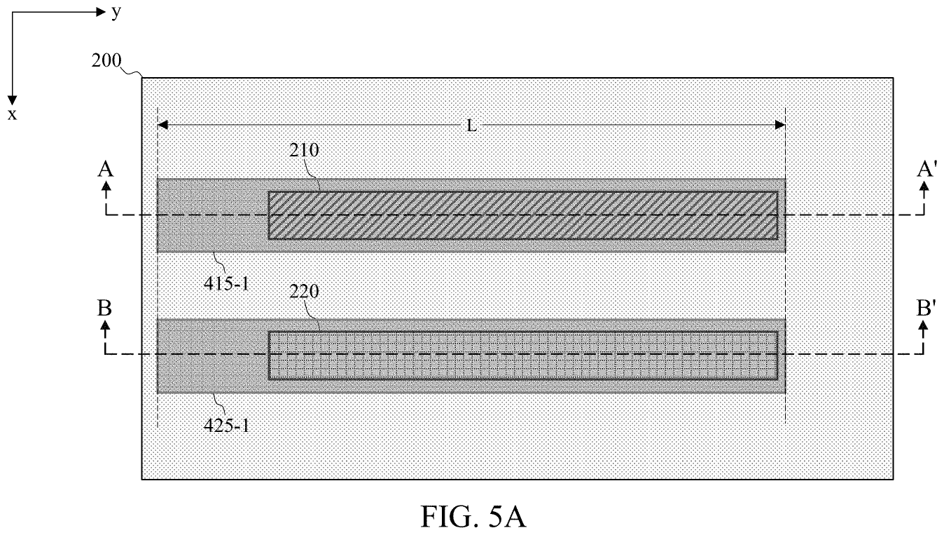

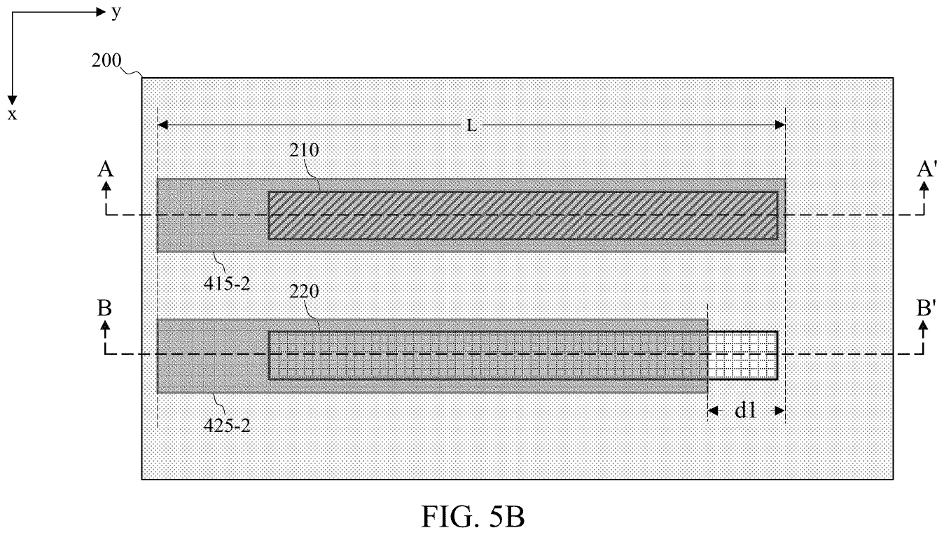

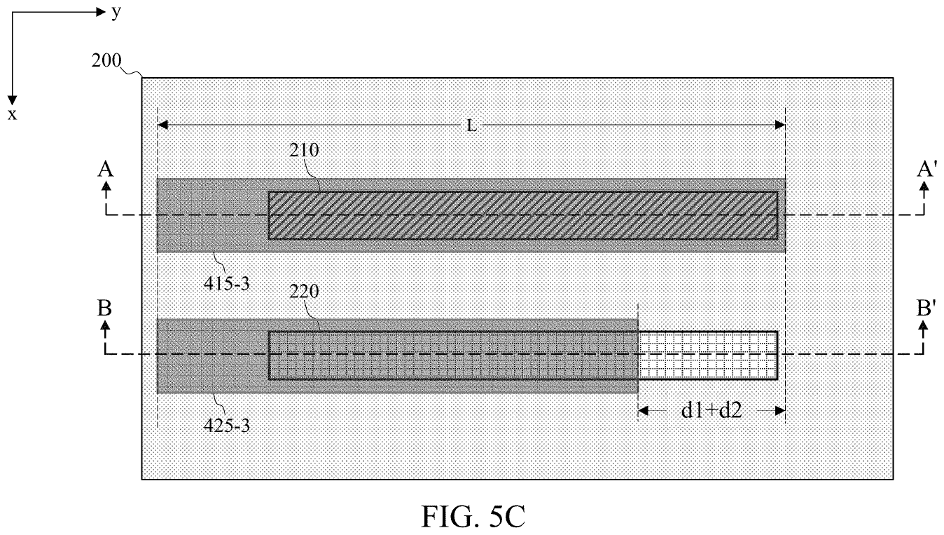

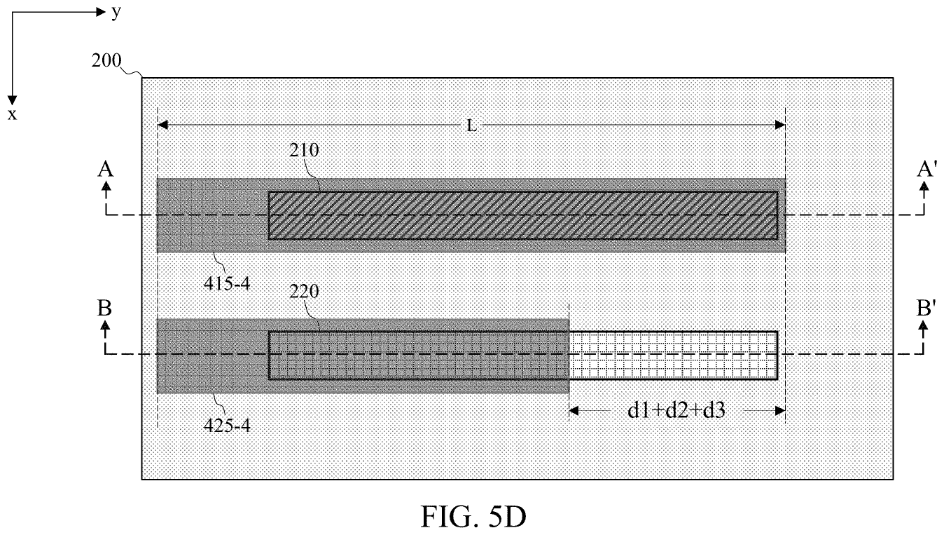

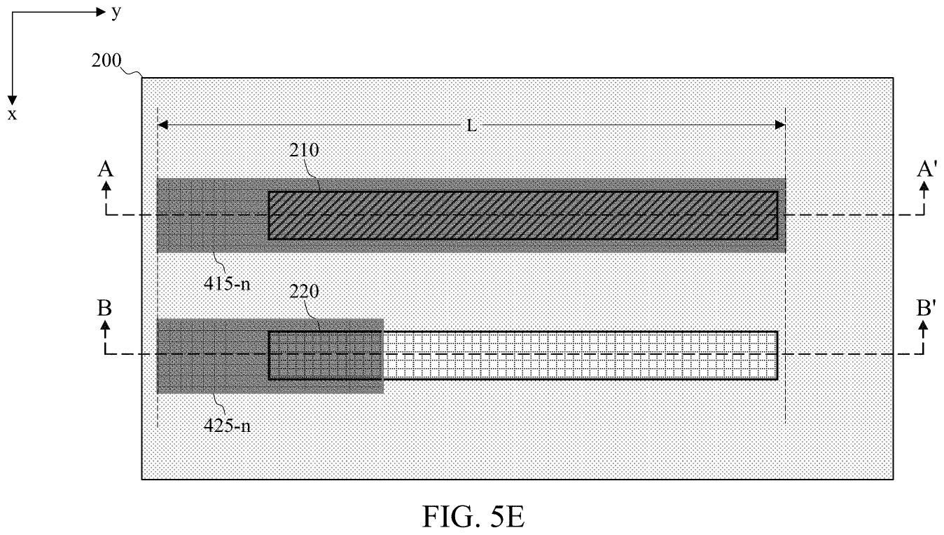

FIGS. 5A-5E show multiple cross-sectional top views of a diode according to an embodiment of the present invention, and these top views respectively show the relationship between one of the conductor layers and the doped regions on the substrate. FIGS. 5A-5E correspond to the cross-sectional side views of FIGS. 4A-4B.

FIG. 5A shows the correspondence between the conductors 415-1 and 425-1 in the metal layer M1 and the doped regions 210 and 220. The conductor 415-1 completely covers the doped region 210 and is substantially parallel to the doped region 210. The conductor 425-1 completely covers the doped region 220 and is substantially parallel to the doped region 220. The conductor 415-1 and the conductor 425-1 are substantially parallel. The lengths of the conductor 415-1 and the conductor 425-1 are both L.

FIG. 5B shows the correspondence between the conductors 415-2 and 425-2 in the metal layer M2 and the doped regions 210 and 220. The conductor 415-2 completely covers the doped region 210 and is substantially parallel to the doped region 210. The conductor 425-2 partially covers the doped region 220 and is substantially parallel to the doped region 220. The conductor 415-2 and the conductor 425-2 are substantially parallel. The length of the conductor 415-2 is L, and the length difference between the conductor 415-2 and the conductor 425-2 is d1.

FIG. 5C shows the correspondence between the conductors 415-3 and 425-3 in the metal layer M3 and the doped regions 210 and 220. The conductor 415-3 completely covers the doped region 210 and is substantially parallel to the doped region 210. The conductor 425-3 partially covers the doped region 220 and is substantially parallel to the doped region 220. The conductor 415-3 and the conductor 425-3 are substantially parallel. The length of the conductor 415-3 is L, and the length difference between the conductor 415-3 and the conductor 425-3 is d1+d2.

FIG. 5D shows the correspondence between the conductors 415-4 and 425-4 in the metal layer M4 and the doped regions 210 and 220. The conductor 415-4 completely covers the doped region 210 and is substantially parallel to the doped region 210. The conductor 425-4 partially covers the doped region 220 and is substantially parallel to the doped region 220. The conductor 415-4 and the conductor 425-4 are substantially parallel. The length of the conductor 415-4 is L, and the length difference between the conductor 415-4 and the conductor 425-4 is d1+d2+d3.

FIG. 5E shows the correspondence between the conductors 415-n and 425-n in the metal layer Mn and the doped regions 210 and 220. The conductor 415-n completely covers the doped region 210 and is substantially parallel to the doped region 210. The conductor 425-n partially covers the doped region 220 and is substantially parallel to the doped region 220. The conductor 415-n and the conductor 425-n are substantially parallel. The length of the conductor 415-n is L.

Reference is made to FIGS. 4A-4B and FIGS. 5A-5E. The conductor 415-1 and the conductor 425-1 substantially overlap on the y-z plane (the overlapping area A1≈L*h1); the conductor 415-2 and the conductor 425-2 partially overlap on the y-z plane (the overlapping area A2≈(L−d1)*h2); the conductor 415-3 and the conductor 425-3 partially overlap on the y-z plane (the overlapping area A3≈(L−d1−d2)*h3); the conductor 415-4 and the conductor 425-4 partially overlap on the y-z plane (the overlapping area A4≈(L−d1−d2−d3)*h4); and the conductor 415-n and the conductor 425-n partially overlap on the y-z plane (the overlapping area being the smallest among all conductor layers). If all conductor layers are substantially the same in thickness (i.e., h1, h2, h3, h4, hn are substantially the same), then A1>A2>A3>A4.

Because the conductor structure 420 presents the stepped shape (or referred to as a retrograde-type), the overlapping area between the conductor structure 410 and the conductor structure 420 in one conductor layer (on the y-z plane) is different from that in another. More specifically, the overlapping area between the conductor structure 410 and the conductor structure 420 in the metal layer M1 is the largest, followed by that in the metal layer M2, . . . , and that in the metal layer Mn is the smallest. This design can reduce the current loop area between the anode and cathode of the diode, thereby reducing EMI.

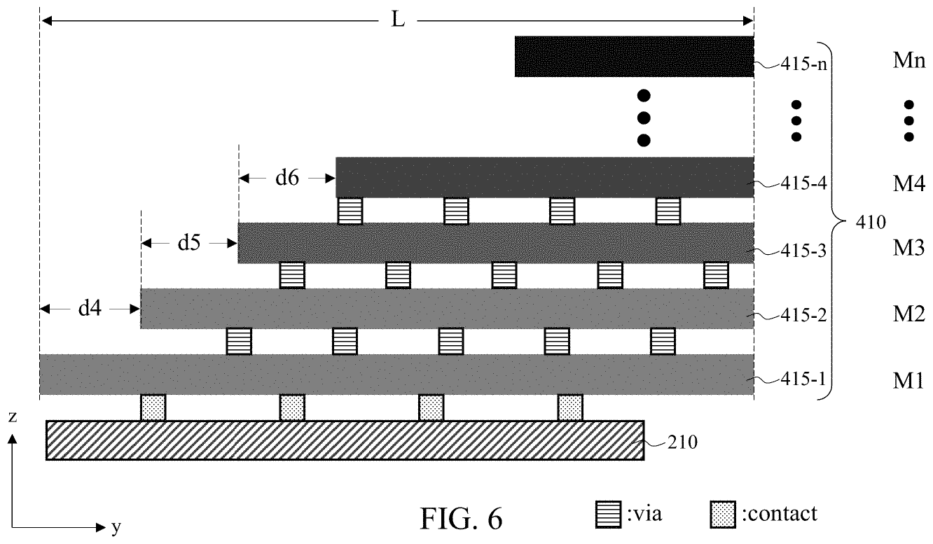

FIG. 6 is a first cross-sectional side view of a diode according to another embodiment of the present invention (corresponding to the cross section A-A′ in FIG. 2). The difference between FIG. 6 and FIG. 4A is that in the embodiment of FIG. 6, the conductor structure 410 presents a stepped shape: the conductor 415-1 is longer than the conductor 415-2 by a length of d4, the conductor 415-2 is longer than the conductor 415-3 by a length of d5, the conductor 415-3 is longer than the conductor 415-4 by a length of d6, . . . , and the conductor 415-n is the shortest conductor in the conductor structure 410. In other words, the conductors in the conductor structure 410 are different in length. As shown in FIG. 6, the conductors 415 in the conductor structure 410 are arranged in a way that their ends on the right side of the side view are substantially aligned. However, the same ends of the conductors being substantially aligned is not a limitation of the present invention. In some embodiments, the lengths of the conductor 415-1, the conductor 415-2, the conductor 415-3, the conductor 415-4, . . . , and the conductor 415-n are in an arithmetic sequence (i.e., d4=d5=d6).

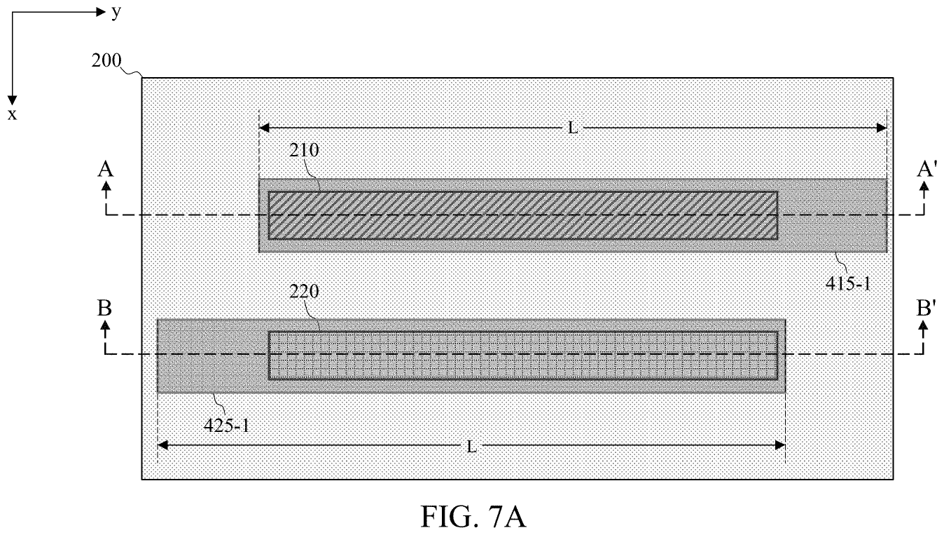

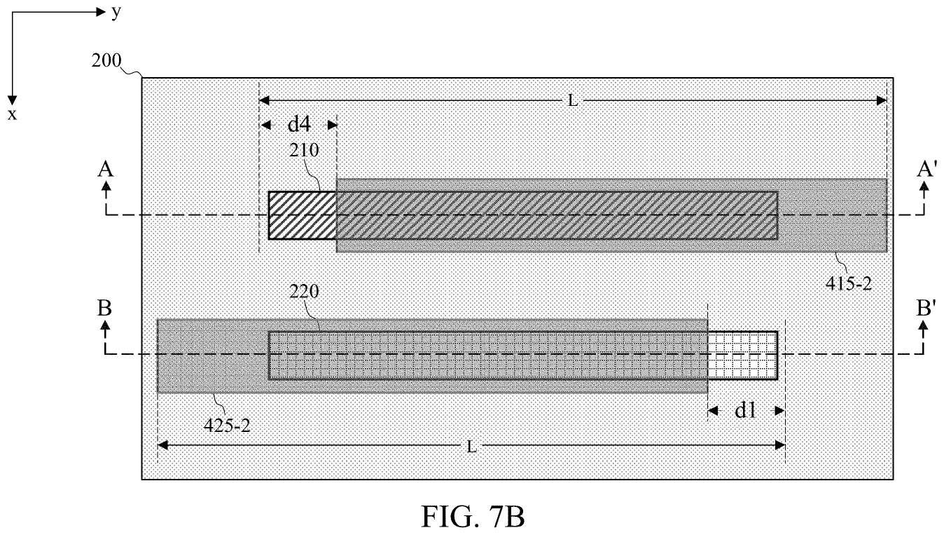

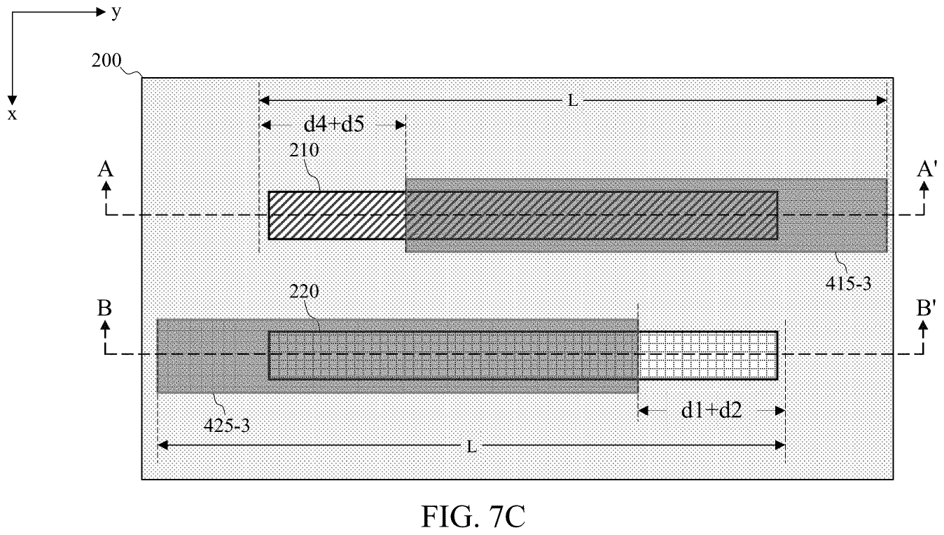

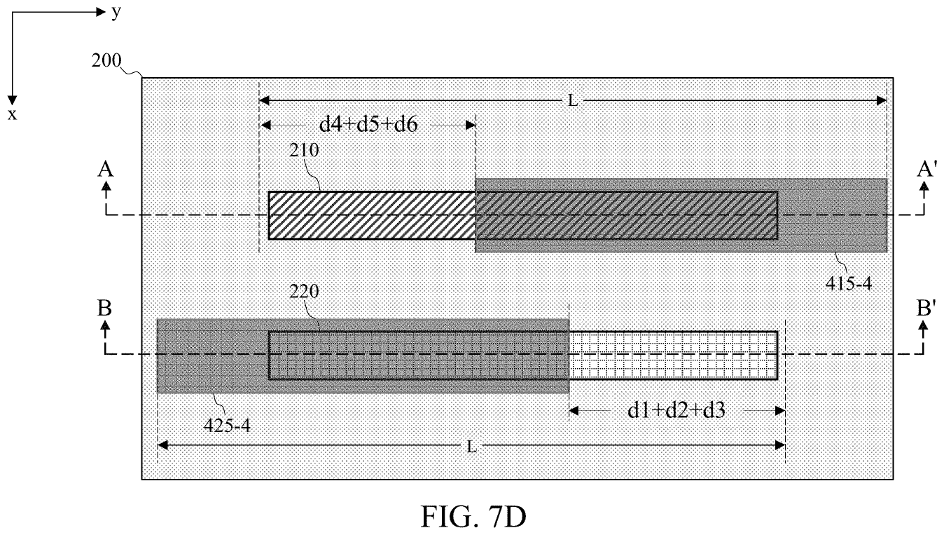

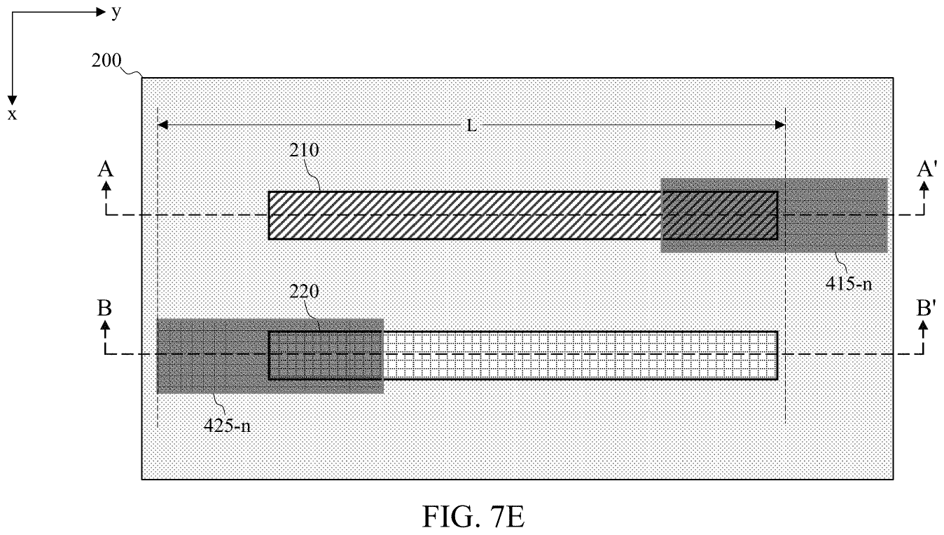

FIGS. 7A-7E show multiple cross-sectional top views of a diode according to another embodiment of the present invention, and these top views respectively show the relationship between one of the conductor layers and the doped regions on the substrate. FIGS. 7A-7E correspond to the cross-sectional side views of FIG. 4B and FIG. 6.

FIG. 7A shows the correspondence between the conductors 415-1 and 425-1 in the metal layer M1 and the doped regions 210 and 220. The conductor 415-1 completely covers the doped region 210 and is substantially parallel to the doped region 210. The conductor 425-1 completely covers the doped region 220 and is substantially parallel to the doped region 220. The conductor 415-1 and the conductor 425-1 are substantially parallel. The lengths of the conductor 415-1 and the conductor 425-1 are both L.

FIG. 7B shows the correspondence between the conductors 415-2 and 425-2 in the metal layer M2 and the doped regions 210 and 220. The conductor 415-2 partially covers the doped region 210 and is substantially parallel to the doped region 210. The conductor 425-2 partially covers the doped region 220 and is substantially parallel to the doped region 220. The conductor 415-2 and the conductor 425-2 are substantially parallel. The length of the conductor 415-2 is (L−d4), and the length of the conductor 425-2 is (L−d1).

FIG. 7C shows the correspondence between the conductors 415-3 and 425-3 in the metal layer M3 and the doped regions 210 and 220. The conductor 415-3 partially covers the doped region 210 and is substantially parallel to the doped region 210. The conductor 425-3 partially covers the doped region 220 and is substantially parallel to the doped region 220. The conductor 415-3 and the conductor 425-3 are substantially parallel. The length of the conductor 415-3 is (L−d4−d5), and the length of the conductor 425-3 is (L−d1−d2).

FIG. 7D shows the correspondence between the conductors 415-4 and 425-4 in the metal layer M4 and the doped regions 210 and 220. The conductor 415-4 partially covers the doped region 210 and is substantially parallel to the doped region 210. The conductor 425-4 partially covers the doped region 220 and is substantially parallel to the doped region 220. The conductor 415-4 and the conductor 425-4 are substantially parallel. The length of the conductor 415-4 is (L−d4−d5−d6), and the length of the conductor 425-4 is (L−d1−d2−d3).

FIG. 7E shows the correspondence between the conductors 415-n and 425-n in the metal layer Mn and the doped regions 210 and 220. The conductor 415-n partially covers the doped region 210 and is substantially parallel to the doped region 210. The conductor 425-n partially covers the doped region 220 and is substantially parallel to the doped region 220. The conductor 415-n and the conductor 425-n are substantially parallel.

Reference is made to FIG. 4B, FIG. 6, and FIGS. 7A-7E. Because the conductor structure 410 and the conductor structure 420 both present the stepped shape, the overlapping area between the conductor structure 410 and the conductor structure 420 in one conductor layer (on the y-z plane) is different from that in another. More specifically, the overlapping area between the conductor structure 410 and the conductor structure 420 in the metal layer M1 is the largest, followed by that in the metal layer M2, . . . , and that in the metal layer Mn is the smallest (or no overlap). In comparison with the preceding embodiment (i.e., the embodiments corresponding to FIGS. 4A-4B and FIGS. 5A-5E), the overall overlapping area between the conductor structure 410 and the conductor structure 420 is smaller; therefore, the EMI can be further reduced.

It should be noted that whether the doped region 210 and the doped region 220 are parallel and whether the two conductors in each conductor layer are parallel are not essential to the implementation of the present invention. The two components that are substantially parallel in the preceding discussions can also be designed to be non-parallel.

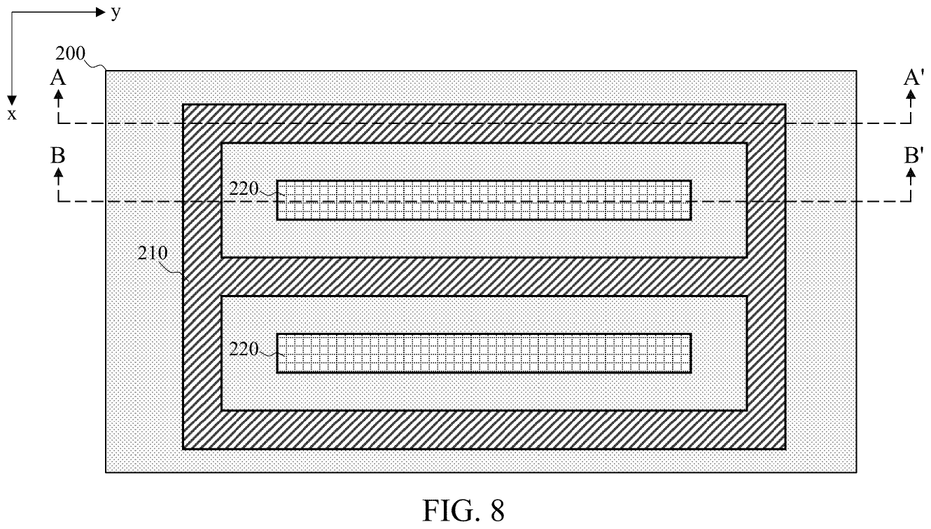

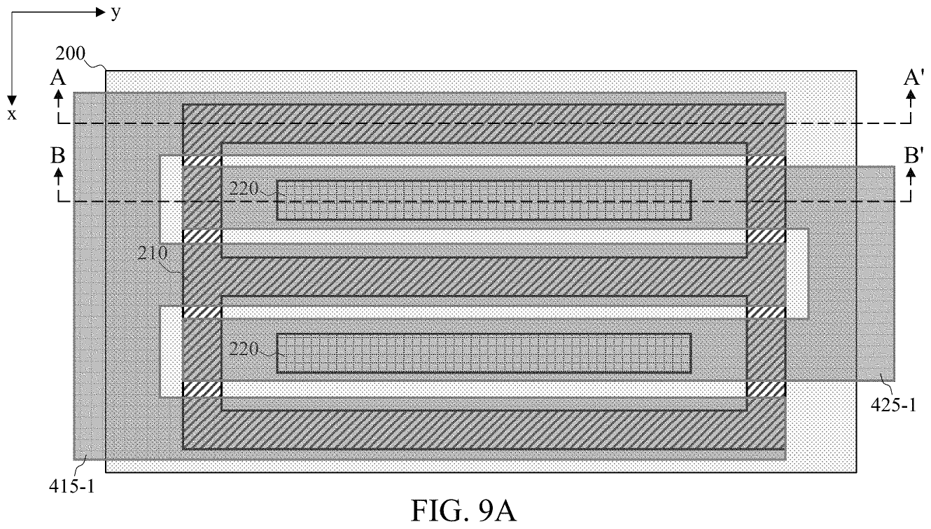

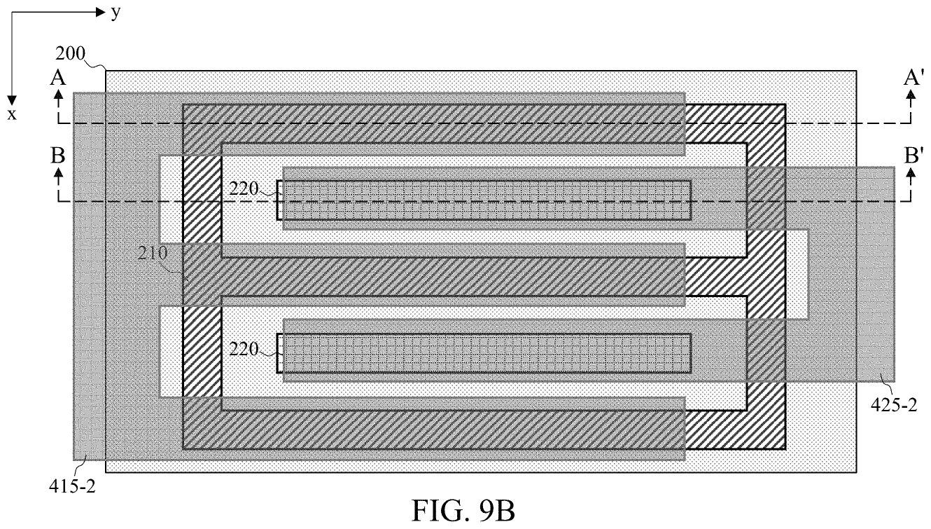

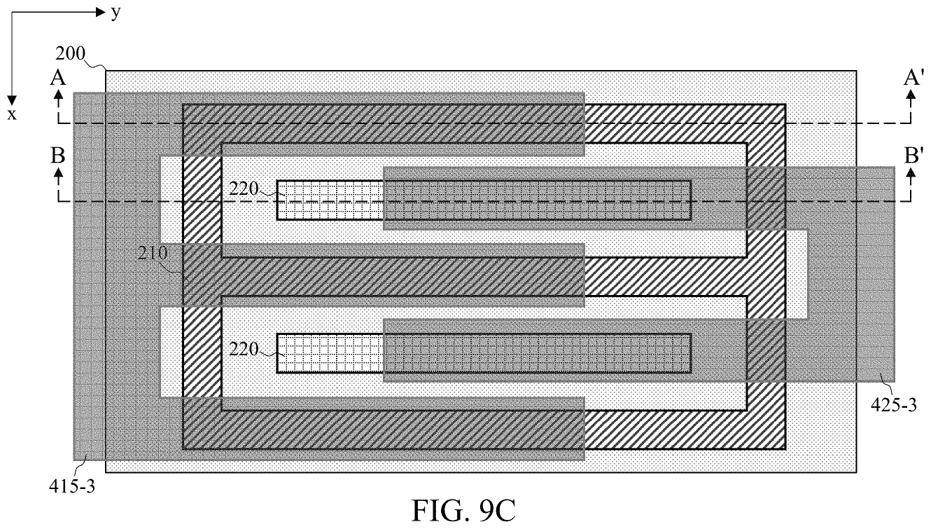

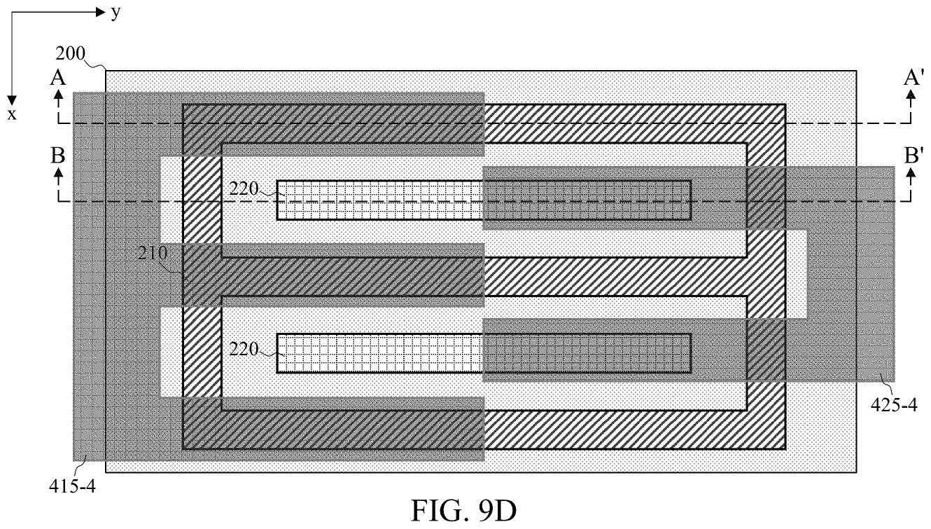

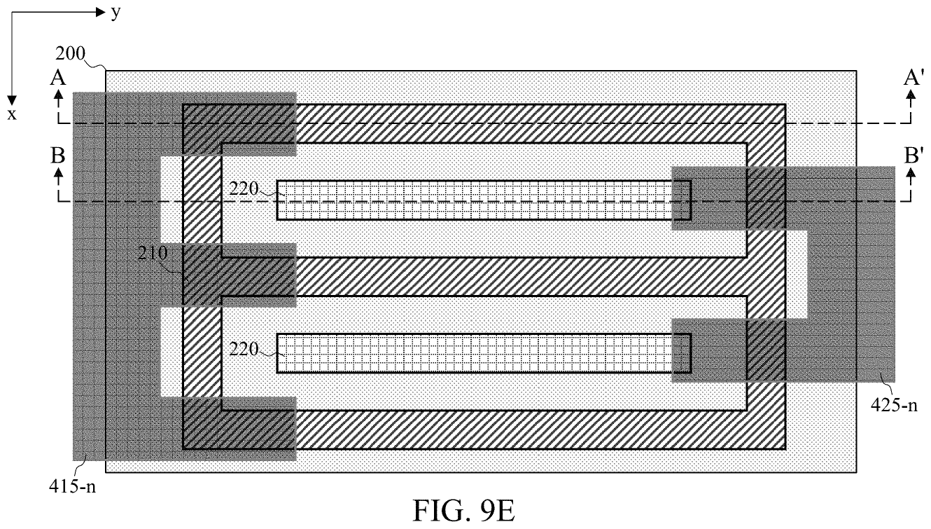

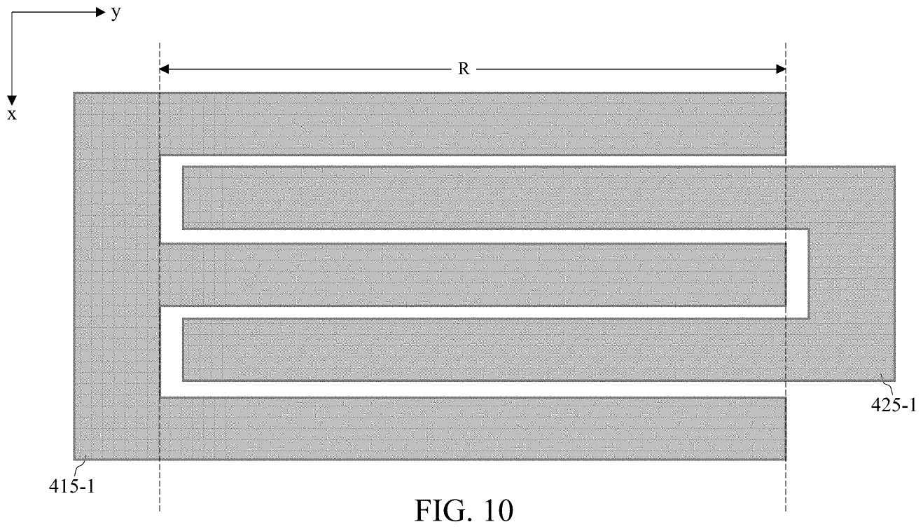

The layout of FIG. 2 serves merely as an example of the diode of the present invention. FIG. 8 illustrates a diode's layout on the substrate according to another embodiment of the present invention. The doped region 210 surrounds the doped region 220. FIGS. 9A-9E show a plurality of cross-sectional top views of a diode according to another embodiment of the present invention, and these top views respectively show the relationship between one of the conductor layers and the doped regions on the substrate. FIGS. 9A-9E correspond to the cross-sectional side views of FIGS. 4B and 6. People having ordinary skill in the art can understand the implementation details and variations of FIG. 8 and FIGS. 9A-9E based on the embodiments discussed above, and the details are thus omitted for brevity. Note that, in the embodiment of FIGS. 9A-9E, the conductor 415 presents an “E” shape, and the conductor 425 presents an “U” shape (as shown in FIG. 10, taking the conductor 415-1 and the conductor 425-1 for example), the lengths of the finger structure (the parts in the range R) of the “E”-shaped conductor 415 gradually decreases from FIG. 9A to FIG. 9E, and the lengths of the finger structure (the parts in the range R) of the “U”-shaped conductor 425 gradually decreases from FIG. 9A to FIG. 9E.

The shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A diode in a semiconductor structure comprising:
a substrate comprising a first doped region and a second doped region, wherein the first doped region is a first electrode of the diode, the second doped region is a second electrode of the diode, and a dopant in the first doped region is different from a dopant in the second doped region;
a first conductor structure arranged above the first doped region, connected to the first doped region, and including a plurality of first conductors that are arranged in a plurality of conductor layers of the semiconductor structure and connected to each other by a plurality of vias; and
a second conductor structure arranged above the second doped region, connected to the second doped region, and including a plurality of second conductors that are arranged in the conductor layers of the semiconductor structure and connected to each other by a plurality of vias;
wherein a cross-sectional side view of the first conductor structure is in a stepped shape.

2. The diode of claim 1, wherein the first conductor closest to the substrate is the longest among the first conductors, and the lengths of other first conductors gradually decrease.

3. The diode of claim 1, wherein a cross-sectional side view of the second conductor structure presents a stepped shape.

4. The diode of claim 3, wherein the first conductor closest to the substrate is the longest among the first conductors, and the lengths of other first conductors gradually decrease.

5. The diode of claim 4, wherein the second conductor closest to the substrate is the longest among the second conductors, and the lengths of other second conductors gradually decrease.

6. The diode of claim 5, wherein ends of the first conductors on a left side of the cross-sectional side view are substantially aligned, and ends of the second conductors on a right side of the cross-sectional side view are substantially aligned.

7. The diode of claim 1, wherein the first doped region and the second doped region are substantially parallel to each other.

8. The diode of claim 7, wherein the first conductor structure and the second conductor structure are substantially parallel to each other.

9. A diode, implemented in a semiconductor structure, comprising:
a substrate comprising a first doped region and a second doped region, wherein the first doped region is used as a first electrode of the diode, the second doped region is used as a second electrode of the diode, and a dopant in the first doped region is different from a dopant in the second doped region;
a first conductor arranged in a first conductor layer of the semiconductor structure and connected to the first doped region;
a second conductor arranged in a second conductor layer of the semiconductor structure and connected to the first conductor;
a third conductor arranged in the first conductor layer of the semiconductor structure and connected to the second doped region; and
a fourth conductor arranged in the second conductor layer of the semiconductor structure and connected to the third conductor;
wherein in a cross-sectional side view of the semiconductor structure, an overlapping area between the first conductor and the third conductor is larger than an overlapping area between the second conductor and the fourth conductor.

10. The diode of claim 9, wherein the first conductor is arranged between the substrate and the second conductor, and the third conductor is arranged between the substrate and the fourth conductor.

11. The diode of claim 10, wherein in a cross-sectional top view or the cross-sectional side view of the semiconductor structure, a length of the second conductor is smaller than a length of the first conductor.

12. The diode of claim 11, wherein in the cross-sectional top view or the cross-sectional side view of the semiconductor structure, a length of the fourth conductor is smaller than a length of the third conductor.

13. The diode of claim 12, wherein ends of the first conductor and the second conductor on a left side of the cross-sectional side view are substantially aligned, and ends of the third conductor and the fourth conductor on a right side of the cross-sectional side view are substantially aligned.

14. The diode of claim 9, wherein the first doped region and the second doped region are substantially parallel to each other.

15. The diode of claim 9, wherein the first conductor and the third conductor are substantially parallel to each other, and the second conductor and the fourth conductor are substantially parallel to each other.
